(19) United States
(12) Patent Application Publication
(10) Pub. No.: US 2015/0187680 A1
(43) Pub. Date: Jul. 2, 2015

(54) SEMICONDUCTOR APPARATUS, MANUFACTURING METHOD THEREOF AND TESTING METHOD THEREOF

(71) Applicant: SK hynix Inc., Icheon-si Gyeonggi-do (KR)

(72) Inventor: Ji Tai SEO, Icheon-si Gyeonggi-do (KR)

(73) Assignee: SK hynix Inc., Icheon-si Gyeonggi-do (KR)

(21) Appl. No.: 14/207,940

(22) Filed: Mar. 13, 2014

(30) Foreign Application Priority Data
Dec. 30, 2013 (KR) 10-2013-0167025

(51) Int. Cl. H01L 23/48; G01R 31/27; H01L 21/311; H01L 21/66; H01L 21/768; H01L 23/00

(52) U.S. Cl. CPC H01L 23/481; H01L 21/76898; H01L 24/05; H01L 24/03; H01L 21/31111; H01L 22/14; G01R 31/275; H01L 2224/05025

(57) ABSTRACT

A semiconductor apparatus includes one or more semiconductor chips. Each semiconductor chip includes a semiconductor substrate formed with a through-silicon via, and a bottom wiring layer with a first dielectric layer formed on a bottom of the semiconductor substrate. A first opening is defined in the first dielectric layer.

### CROSS-REFERENCES TO RELATED APPLICATION

The present application claims priority under 35 U.S.C. §119(a) to Korean application number 10-2013-0167025, filed on Dec. 30, 2013, in the Korean Intellectual Property Office, which is incorporated herein by reference in its entirety.

### TECHNICAL FIELD

Various embodiments relate to a semiconductor apparatus, and more particularly, to a semiconductor apparatus which may easily test a TSV (through-silicon via) fail of a unit semiconductor chip without the need of performing a back-grinding process in the manufacture of the unit semiconductor chip.

### BACKGROUND

The method of mounting a plurality of semiconductor chips in one semiconductor package is divided into a method of horizontally mounting semiconductor chips and a method of vertically mounting semiconductor chips.

In this regard, due to the characteristic of an electronic product that trends toward miniaturization, most semiconductor apparatuses are manufactured into stack-type multi-chip packages in which semiconductor chips are packaged by being vertically stacked.

### SUMMARY

In an embodiment, a semiconductor apparatus may include one or more semiconductor chips. Each semiconductor chip includes a semiconductor substrate formed with a through-silicon via and a bottom wiring layer formed on a bottom of the semiconductor substrate. The bottom wiring layer includes a first dielectric layer formed on a bottom of the semiconductor substrate. A first opening may be defined in the first dielectric layer.

In an embodiment, a method for manufacturing a semiconductor apparatus may include: forming a bottom wiring layer which has a through-silicon via pad, on a bottom of a semiconductor substrate; and forming a through-silicon via electrically coupled with the through-silicon via pad, in the semiconductor substrate.

In an embodiment, a method for testing a semiconductor apparatus includes providing the semiconductor chip with features described above; and testing a fail of the through-silicon via by electrically coupling a through-silicon via fail detection system through the first opening and the second opening.

In an embodiment, a system comprises: a processor, a controller that is configured to receive a request and a data from the processor, and a memory unit configured to receive the request and the data from the controller. The memory unit includes one or more semiconductor chips. Each semiconductor chip comprises a semiconductor substrate formed with a through-silicon via, and a bottom wiring layer with a dielectric layer formed on a bottom of the semiconductor substrate. An opening is defined in the dielectric layer.

### BRIEF DESCRIPTION OF THE DRAWINGS

FIG. 1 is a view schematically showing a semiconductor apparatus in accordance with an embodiment;

FIG. 2 is a cross-sectional view showing each semiconductor chip of the semiconductor apparatus in accordance with an embodiment;

FIG. 3 is a cross-sectional view showing a state in which respective semiconductor chips are stacked in the semiconductor apparatus in accordance with an embodiment;

FIG. 4 is a cross-sectional view showing each semiconductor chip of a semiconductor apparatus in accordance with an embodiment;

FIG. 5 is a flow chart explaining a method for manufacturing a semiconductor apparatus in accordance with an embodiment;

FIG. 6 is a view explaining a method for testing a TSV fail of each semiconductor chip in the semiconductor apparatus in accordance with an embodiment; and

FIG. 7 is a flow chart explaining a method for manufacturing a semiconductor apparatus in accordance with an embodiment.

### DETAILED DESCRIPTION

A semiconductor apparatus continuously trends toward high degree of integration, high capacity and high speed operation. After performing a back-grinding process on the bottom surface of the semiconductor substrate to expose the bottom surface of the TSV, a bottom surface bump pad is formed to be electrically coupled with the bottom surface of the TSV. A method for testing a TSV fail of each semiconductor chip before the stack process is demanded. If the thickness of the semiconductor substrate is decreased by the back-grinding process, the internal circuit of the semiconductor apparatus is likely to be damaged. In addition, as the material constituting the TSV is exposed to an outside in the back-grinding process, a problem may occur due to oxidation, etc. Further, TSV smearing in which the TSV is also grinded may occur, or the semiconductor substrate is likely to be damaged. Hereinafter, a semiconductor apparatus, a manufacturing method thereof and a testing method thereof according to the present disclosure will be described below with reference to the accompanying drawings through exemplary embodiments.

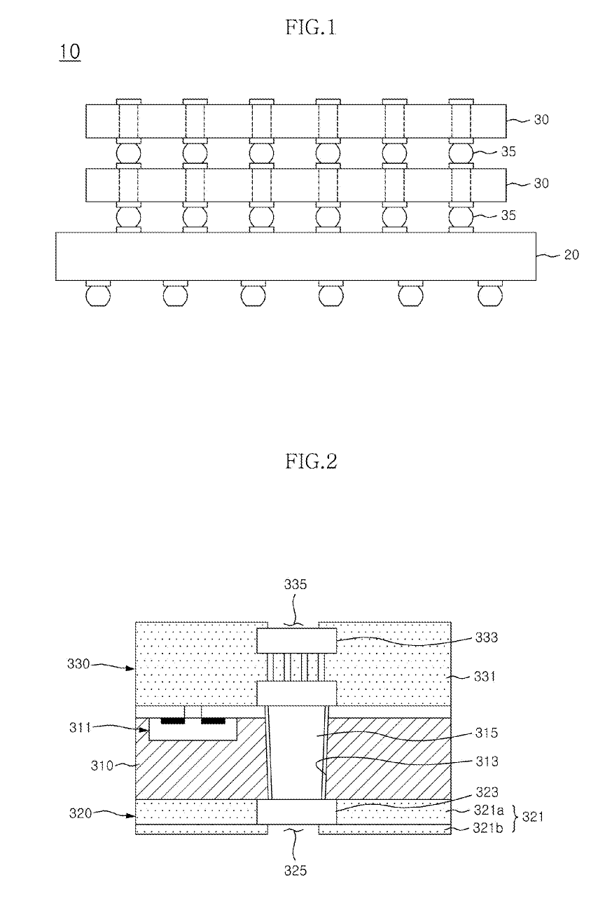

Referring to FIG. 1, a semiconductor apparatus 10 includes a substrate 20, and one or more semiconductor chips 30 which are stacked over the substrate 20. While it is shown in the drawing that two semiconductor chips 30 are stacked over the substrate 20, it is to be noted that various numbers of semiconductor chips may be stacked.

An underfill member (not shown) may be filled in the space between the substrate 20 and the one or more semiconductor chips 30. An underfill member (not shown) may be filled even in the space between the semiconductor chips 30.

The substrate 20 may be formed of various materials. For example, the substrate 20 may be formed of a material such as silicon, ceramic, polymer, metal, glass, and so forth. The substrate 20 may include an integrated circuit (not shown) therein; and may transfer power from an exterior through the integrated circuit to the one or more semiconductor chips 30 or may exchange electrical signals with an exterior through the integrated circuit.

The semiconductor chips 30 may be stacked over the substrate 20 as described above. The configuration of such semiconductor chips 30 will be described below in detail.

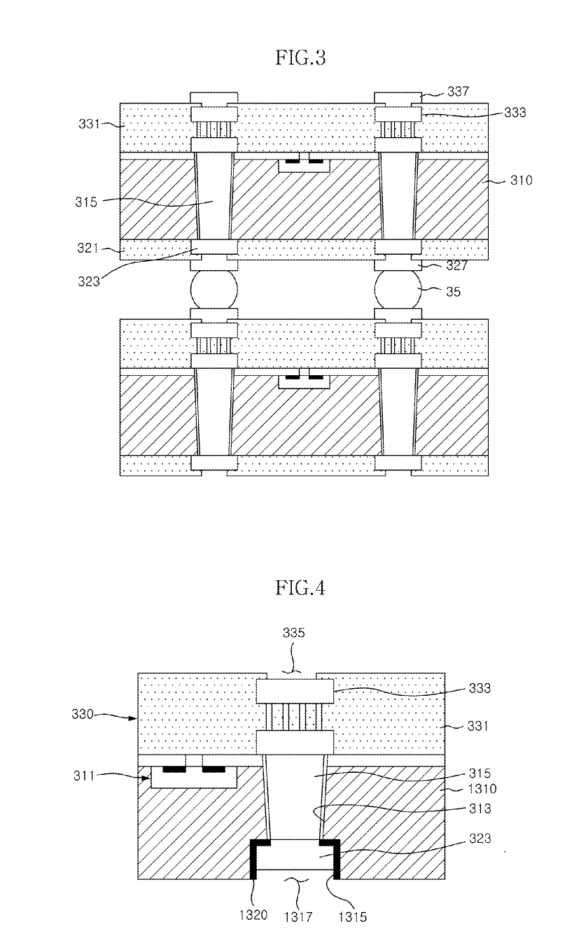

Referring to FIGS. 2 and 3, each semiconductor chip 30 includes a semiconductor substrate 310, a bottom wiring layer 320 formed on the bottom of the semiconductor substrate 310, and a top wiring layer 330 formed on the top of the semiconductor substrate 310.

An internal circuit 311 is formed in the semiconductor substrate 310. The internal circuit 311 may include a transistor, a capacitor, a resistor, and so forth. Only a transistor is shown in the drawing.

A via hole 313 is defined in the semiconductor substrate 310. The via hole 313 may be defined into a cross-sectional shape which passes through the semiconductor substrate 310 as shown in the drawings. A TSV (through-silicon via) 315 is formed through a process of filling a conductive material in the via hole 313. For example, the conductive material filled in the via hole 313 may be copper (Cu).

The bottom wiring layer 320 may include a first dielectric layer 321 formed on the bottom surface of the semiconductor substrate 310, and a conductive pad 323 formed in the first dielectric layer 321.

The conductive pad 323 may be electrically coupled with the bottom end of the TSV 315 in the first dielectric layer 321.

The first dielectric layer 321 is formed on the bottom surface of the semiconductor substrate 310 as described above. A first opening 325 is defined in the first dielectric layer 321 such that the surface of the conductive pad 323 may be exposed and allow the TSV 315 to be electrically coupled with an exterior. A bottom surface bump pad (that is, a first bump pad) 327 which is electrically coupled with a bump 35 (also illustrated in FIG. 1) disposed between the semiconductor chips 30 may be formed in the first opening 325. As the first bump pad 327 is disposed in the first opening 325, the first bump pad 327 and the conductive pad 323 may be electrically coupled with each other.

The top wiring layer 330 is formed on the top of the semiconductor substrate 310 as described above. The top wiring layer 330 may include a second dielectric layer 331 which is formed on the top surface of the semiconductor substrate 310, and a conductive line 333 which is formed in the second dielectric layer 331.

The conductive line 333 may be formed in the second dielectric layer 331 in such a way as to form one or more layer. The conductive line 333 may be electrically coupled with the top end of the TSV 315 and a top surface bump pad (that is, a second bump pad) 337.

For example, the conductive line 333 may be formed into multiple layers in the second dielectric layer 331. The lowermost layer of the conductive line 333 which is formed into multiple layers in this way may be electrically coupled with the top end of the TSV 315; and the uppermost layer of the conductive line 333 which is formed into multiple layers may be electrically coupled with the second bump pad 337. The lowermost and uppermost layers of the conductive line 333 may be electrically coupled with each other through contacts.

The second dielectric layer 331 is formed on the top surface of the semiconductor substrate 310 as described above. A second opening 335 is defined in the second dielectric layer 331 such that the surface of the conductive line 333 may be exposed. The second bump pad 337 which is electrically coupled with a bump 35 disposed between the semiconductor chips 30 may be formed in the second opening 335. As the second bump pad 337 is disposed in the second opening 335, the second bump pad 337 and the conductive line 333 may be electrically coupled with each other.

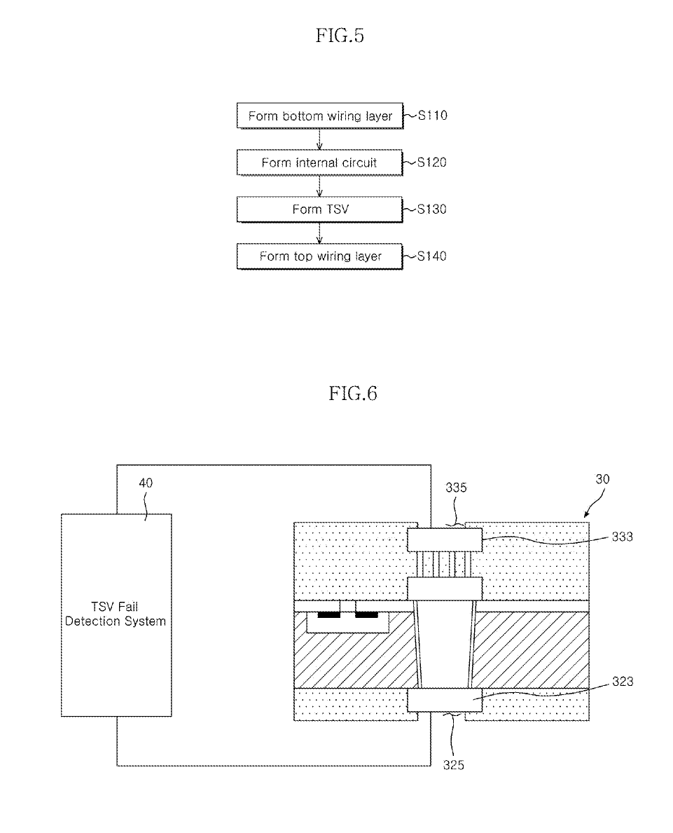

The configuration of a semiconductor chip in accordance with an embodiment will be described below in detail with reference to FIG. 4.

A semiconductor chip 30 includes a semiconductor substrate 1310 and a top wiring layer 330 which is formed on the top of the semiconductor substrate 1310.

The semiconductor substrate 1310 is formed with an internal circuit 311 and is defined with a via hole 313. A TSV pad groove 1315 is defined on the bottom surface of the semiconductor substrate 1310. A TSV pad dielectric layer 1320 is formed in the TSV pad groove 1315 that may isolate a TSV pad 323 from the semiconductor substrate 1310; and the TSV pad 323 electrically coupled to the TSV 315 is disposed in the TSV pad groove 1315 in such a way as to be seated on the TSV pad dielectric layer 1320. A first opening 1317 is defined in the TSV pad dielectric layer 1320 such that the surface of the TSV pad 323 may be exposed.

The top wiring layer 330 may include a dielectric layer 331 which is formed on the top surface of the semiconductor substrate 1310, and a conductive line 333 which is formed in the dielectric layer 331. A second opening 335 is defined in the second dielectric layer 331 such that the surface of the conductive line 333 may be exposed.

Hereinafter, a method for manufacturing a unit semiconductor chip of a semiconductor apparatus in accordance with an embodiment will be described with reference to FIGS. 2, 3 and 5.

The bottom wiring layer 320 is formed on the bottom surface of the semiconductor substrate 310 (S110). The bottom wiring layer 320 may be formed through processes of forming a first-first dielectric layer 321a on the bottom surface of the semiconductor substrate 310; etching a predetermined region (a region corresponding to the TSV 315 to be formed in the semiconductor substrate 310) of the first-first dielectric layer 321a; forming the TSV pad 323 which is electrically coupled to the TSV 315 in the predetermined region of the first-first dielectric layer 321a; forming and etching a first-second dielectric layer 321b; and defining the first opening 325 in which the first bump pad 327 is to be disposed, in the first-second dielectric layer 321b which exposes the TSV pad 323.

After the bottom wiring layer 320 is formed in this way, the internal circuit 311 is formed in the semiconductor substrate 310 (S120). The internal circuit 311 may include a transistor, a capacitor, a resistor, and so forth.

The TSV 315 is formed in the semiconductor substrate 310 is formed with the bottom wiring layer 320 and the internal circuit 311 (S130). The TSV 315 is formed through processes of defining the via hole 313 at a predetermined position of the semiconductor substrate 310; that is, a position corresponding to the TSV pad 323 of the bottom wiring layer 320; filling a conductive material, for example, copper, in the via hole 313; and planarizing the conductive material in such a way as to expose the top surface of the semiconductor substrate 310.

The top wiring layer 330 is formed on the top surface of the semiconductor substrate 310 (S140). The top wiring layer 330 includes the second dielectric layer 331, and the conductive line 333 which is formed in the second dielectric layer 331 and has one or more layer electrically coupled with one surface of the TSV 315. The second opening 335 may be defined in the second dielectric layer 331 such that the second bump pad 337 may be disposed in the second opening 335.

The unit semiconductor chip 30 which is manufactured through the above-described processes does not undergo a process for back-grinding the semiconductor substrate 310. Due to this fact, the semiconductor chip 30 may prevent the internal circuit 311 from being damaged by back-grinding; prevent the TSV 315 from being exposed to an outside by back-grinding and from being oxidated thereby; and prevent the TSV 315 from being directly damaged.

Also, in the unit semiconductor chip 30 which is manufactured through the above-described processes, as shown in FIG. 6, a TSV fail may be tested before a process for stacking each semiconductor chip 30. This is because it is possible to electrically couple a TSV fail detection system 40 through the openings 325 and 335 due to the fact that the second opening 335 is defined on the top surface of the semiconductor chip 30 to expose the conductive line 333; and the first opening 325 is defined on the bottom surface of the semiconductor chip 30 in such a way as to expose the TSV pad 323.

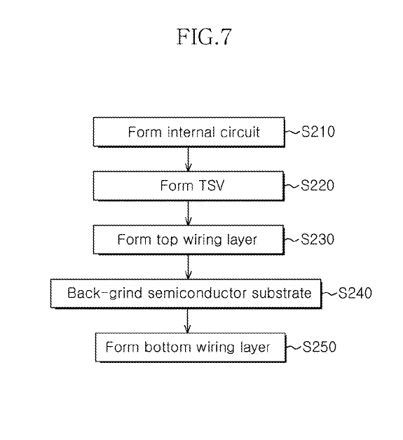

Further, a method for manufacturing a unit semiconductor chip in accordance with an embodiment will be described with reference to FIGS. 2 and 7.

The internal circuit 311 is formed in the semiconductor substrate 310 (S210); the TSV 315 is formed in the semiconductor substrate 310 which is formed with the internal circuit 311 (S220); the top wiring layer 330 is formed on the top surface of the semiconductor substrate 310 which is formed with the TSV 315 (S230); the semiconductor substrate 310 is back-grinded by being turned over (S240); and the bottom wiring layer 320 is formed on the bottom surface of the semiconductor substrate 310 which is back-grinded (S250). Since the steps are the same as those of the aforementioned embodiment, detailed descriptions thereof will be omitted herein.

In the unit semiconductor chip 30 which is manufactured through the above-described processes, similarly to the aforementioned embodiment, since the second opening 335 is defined in the top wiring layer 330 and the first opening 325 is defined in the bottom wiring layer 320, the fail of the TSV 315 may be tested before a process for stacking each semiconductor chip 30.

While certain embodiments have been described above, it will be understood to those skilled in the art that the embodiments described are by way of example only. Accordingly, the semiconductor apparatus, the manufacturing method thereof and the testing method thereof described herein should not be limited based on the described embodiments. Rather, the semiconductor apparatus, the manufacturing method thereof and the testing method thereof described herein should only be limited in light of the claims that follow when taken in conjunction with the above description and accompanying drawings.

What is claimed is:

1. A semiconductor apparatus including one or more semiconductor chips,
wherein each semiconductor chip comprises a semiconductor substrate formed with a through-silicon via, and a bottom wiring layer with a first dielectric layer formed on a bottom of the semiconductor substrate, and
wherein a first opening is defined in the first dielectric layer.

2. The semiconductor apparatus according to claim 1,
wherein the bottom wiring layer further has a first conductive member disposed in the first dielectric layer, and
wherein the first conductive member is electrically coupled with one surface of the through-silicon via and exposed through the first opening.

3. The semiconductor apparatus according to claim 1,
wherein each semiconductor chip further includes a top wiring layer formed on a top of the semiconductor substrate, and
wherein the top wiring layer includes a second dielectric layer formed on a top surface of the semiconductor substrate, and a conductive line disposed in the second dielectric layer and formed as one or more layer.

4. The semiconductor apparatus according to claim 3, wherein a second opening is defined in the second dielectric layer.

5. A semiconductor apparatus including one or more semiconductor chip,
wherein each semiconductor chip includes a semiconductor substrate formed with a through-silicon via, and
wherein a through-silicon via pad groove is defined on the bottom of the semiconductor substrate such that a through-silicon via pad electrically coupled with the through-silicon via is disposed in the through-silicon via pad groove.

6. The semiconductor apparatus according to claim 5, wherein a through-silicon via pad dielectric layer is formed in the through-silicon via pad groove to isolate the through-silicon via pad and the semiconductor substrate from each other.

7. A method for manufacturing a semiconductor apparatus, comprising:
forming a bottom wiring layer which has a through-silicon via pad, on a bottom of a semiconductor substrate; and
forming a through-silicon via electrically coupled with the through-silicon via pad, in the semiconductor substrate.

8. The method according to claim 7, wherein the forming of the bottom wiring layer comprises:
forming a first bottom dielectric layer on the bottom of the semiconductor substrate;
etching a region of the first bottom dielectric layer; and
forming the through-silicon via pad in the region.

9. The method according to claim 8, wherein the region is a region which corresponds to the through-silicon via.

10. The method according to claim 8, wherein, after the forming of the through-silicon via pad in the region, the forming of the bottom wiring layer further comprises:
forming a second bottom dielectric layer; and
etching the second bottom dielectric layer and thereby defining an opening.

11. The method according to claim 7, wherein, after the forming of the through-silicon via, the method further comprises:
forming a top wiring layer which has a conductive member electrically coupled with the through-silicon via, on a top of the semiconductor substrate.

12. A method for testing a semiconductor apparatus, comprising:
providing the semiconductor chip of claim 4; and
testing a fail of the through-silicon via by electrically coupling a through-silicon via fail detection system through the first opening and the second opening.

13. The semiconductor apparatus according to claim 1, further comprising:
a via hole configured to pass through the semiconductor substrate.

14. The semiconductor apparatus according to claim 13, wherein the through-silicon via is formed through the via hole.

15. The semiconductor apparatus according to claim 3, wherein the conductive line is electrically coupled with a top end of the through-silicon via and a top surface bump pad.

16. The semiconductor apparatus according to claim 15, wherein a lower layer of conductive line is electrically coupled to the top end of the through-silicon via and an upper layer of the conductive line is electrically coupled to the top surface bump pad.

17. The semiconductor apparatus according to claim 16, wherein the top surface bump pad is formed in the second opening to allow the conductive line to be electrically coupled to the top surface bump pad.

18. The semiconductor apparatus according to claim 1, wherein the first opening is defined in a through-silicon via pad dielectric layer.

19. The semiconductor apparatus according to claim 4, wherein the first opening is defined with a bump pad disposed in the first dielectric layer.
